(19) United States
(12) Patent Application Publication
(10) Pub. No.: US 2026/0240012 A1
(43) Pub. Date: Aug. 13, 2026

(54) WIRING SUBSTRATE AND SEMICONDUCTOR PACKAGE INCLUDING THE SAME

(71) Applicant: Samsung Electronics Co., Ltd., Suwon-si (KR)

(72) Inventors: Joongsun Kim, Suwon-si (KR); Minkyu Kim, Suwon-si (KR); Seungwon Baek, Suwon-si (KR); Kyuil Hwang, Suwon-si (KR)

(21) Appl. No.: 19/341,921

(22) Filed: Sep. 26, 2025

(30) Foreign Application Priority Data
Feb. 12, 2025 (KR) 10-2025-0017963

(51) Int. Cl. H10W 70/65

(52) U.S. Cl. CPC H10W 70/65; H10W 70/685; H10W 90/724; H10W 90/7295

(57) ABSTRACT

A wiring substrate includes a first wiring layer and a second wiring layer. The first wiring layer includes a first insulating pattern and a first conductive pattern thereon. The second wiring layer includes a second insulating pattern disposed on the first insulating pattern to cover the first conductive pattern and a second conductive pattern disposed on the second insulating pattern. The first conductive pattern includes a pad pattern and a wiring pattern extended from the pad pattern, a ground pattern enclosing the pad pattern in a plan view, and an intervening pattern located between the pad and ground patterns. The intervening pattern may be spaced apart from the pad and ground patterns. A first distance between the pad and ground patterns may be substantially uniform. The intervening pattern may include a plurality of linear patterns connected in series.

### CROSS-REFERENCE TO RELATED APPLICATIONS

This U.S. non-provisional patent application claims priority under 35 U.S.C. § 119 to Korean Patent Application No. 10-2025-0017963, filed on Feb. 12, 2025, in the Korean Intellectual Property Office, the entire contents of which are hereby incorporated by reference.

### BACKGROUND

With the recent advance in the electronics industry, the demand for high-performance, high-speed, and compact electronic components are increasing. To meet this demand, packaging technologies of mounting a plurality of semiconductor chips in a single package are being developed.

A semiconductor package may be configured to facilitate the use of an integrated circuit chip as a component in an electronic product. In general, the semiconductor package may include a printed circuit board (PCB) and a semiconductor chip, which may be mounted on the PCB and may be electrically connected to the PCB by bonding wires or bumps. With the recent development of the electronics industry, a semiconductor package technology is developing in various ways with the goal of miniaturization, weight reduction, and manufacturing cost reduction. Furthermore, as the utilization of this technology expands to different fields, including mass storage devices, several types of semiconductor packages are emerging.

### SUMMARY

In some examples, as multiple semiconductor chips and multiple semiconductor devices may be mounted on a substrate, there is an increasing demand for higher wire density in the substrate. For example, it may be desired to reduce the linewidth or scale of the wires, and this may lead to various structural issues in the substrate.

The present disclosure provides a wiring substrate with improved structural stability and a semiconductor package including the same.

In general, in some aspects, the present disclosure provides a method of reducing a failure in a process of fabricating a wiring substrate and a method of fabricating a semiconductor package.

In general, in some aspects, the present disclosure provides a wiring substrate that may include a first wiring layer and a second wiring layer disposed on the first wiring layer. The first wiring layer may include a first insulating pattern and a first conductive pattern disposed on the first insulating pattern. The second wiring layer may include a second insulating pattern disposed on the first insulating pattern to cover the first conductive pattern, and a second conductive pattern disposed on the second insulating pattern. The first conductive pattern may include a pad pattern and a wiring pattern extended from the pad pattern, a ground pattern enclosing the pad pattern, when viewed in a plan view, and an intervening pattern located between the pad pattern and the ground pattern. The intervening pattern may be spaced apart from the pad pattern and the ground pattern. A first distance between the pad pattern and the ground pattern may be substantially uniform. The intervening pattern may include a plurality of linear patterns connected in series.

In general, in some aspects, the present disclosure provides a wiring substrate that may include a first wiring layer and a second wiring layer disposed on the first wiring layer. The first wiring layer may include a first insulating pattern and a conductive pattern disposed on the first insulating pattern. The second wiring layer may include a second insulating pattern provided on the first insulating pattern to cover the conductive pattern, and an under-bump pattern disposed on the second insulating pattern and coupled with an outer terminal. The conductive pattern may include a pad pattern and a wiring pattern extended from the pad pattern, an intervening pattern extended along a side surface of the pad pattern and side surfaces of the wiring pattern and spaced apart from the pad pattern and the wiring pattern by a first distance, and a ground pattern provided to enclose the pad pattern and the wiring pattern and spaced apart from the pad pattern and the wiring pattern by a second distance larger than the first distance. The under-bump pattern may be placed on the pad pattern. The under-bump pattern may have a side surface crossing the wiring pattern and the intervening pattern, when viewed in a plan view.

In general, in some aspects, the present disclosure provides a semiconductor package that includes a wiring substrate, a semiconductor chip mounted on the wiring substrate, and a connection terminal placed between the wiring substrate and the semiconductor chip to connect the semiconductor chip to the wiring substrate. The wiring substrate may include a first insulating pattern, a conductive pattern disposed on the first insulating pattern, a second insulating pattern disposed on the first insulating pattern to cover the conductive pattern, and an under-bump pattern disposed on the second insulating pattern and coupled to the connection terminal. The conductive pattern may include a pad pattern and a wiring pattern extended from the pad pattern, a ground pattern enclosing the pad pattern in a plan view, and an intervening pattern placed between the ground pattern and the pad pattern and between the ground pattern and the wiring pattern. The under-bump pattern may be placed on a connecting portion between the pad pattern and the wiring pattern, and the intervening pattern may include a plurality of linear patterns connected in series.

### BRIEF DESCRIPTION OF THE DRAWINGS

FIG. 1 is a sectional view illustrating an example of a wiring substrate.

FIG. 2 is an enlarged sectional view illustrating a portion A of FIG. 1.

FIGS. 3 and 4 are plan views corresponding to the structure of FIG. 2.

FIG. 5 is an enlarged sectional view illustrating a portion B of FIG. 1.

FIG. 6 is a plan view corresponding to the structure of FIG. 5.

FIG. 7 is an enlarged sectional view illustrating a portion C of FIG. 1.

FIG. 8 is a plan view corresponding to the structure of FIG. 7.

FIGS. 9 and 10 are sectional views illustrating an example of a semiconductor package.

FIGS. 11 to 24 are diagrams illustrating an example method of fabricating a wiring substrate.

### DETAILED DESCRIPTION

Example implementations will now be described more fully with reference to the accompanying drawings, in which example implementations are shown.

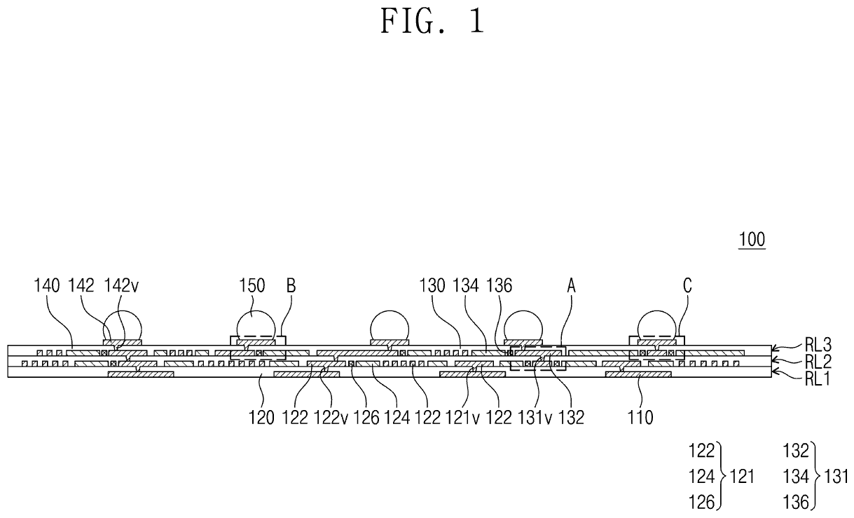

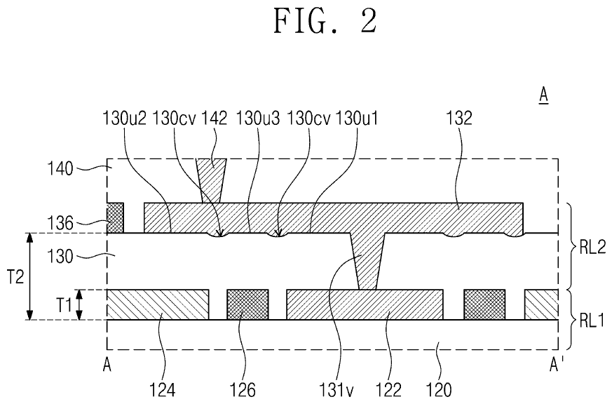

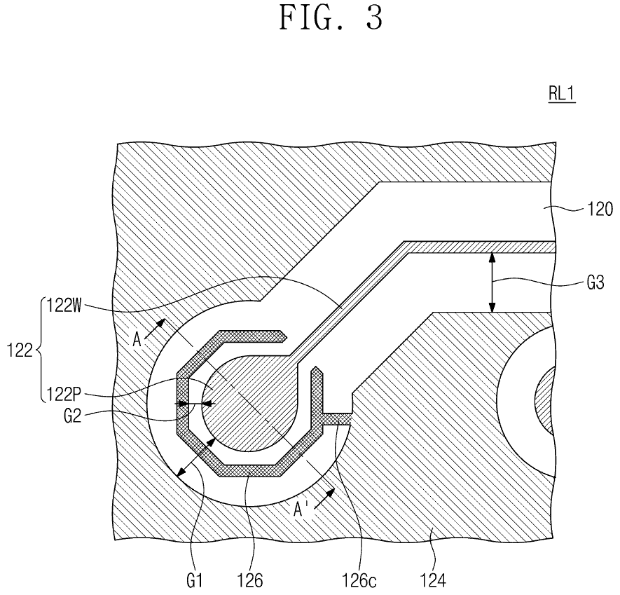

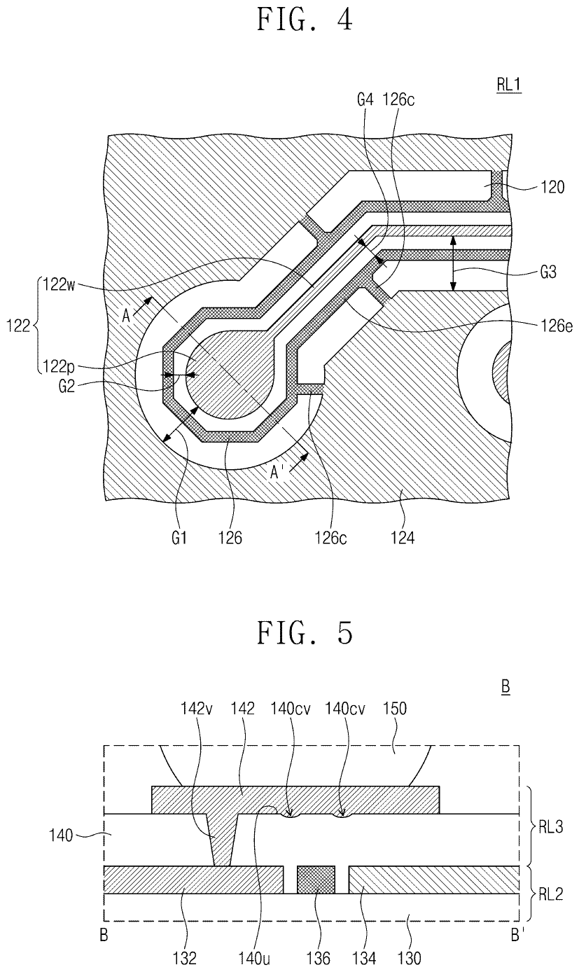

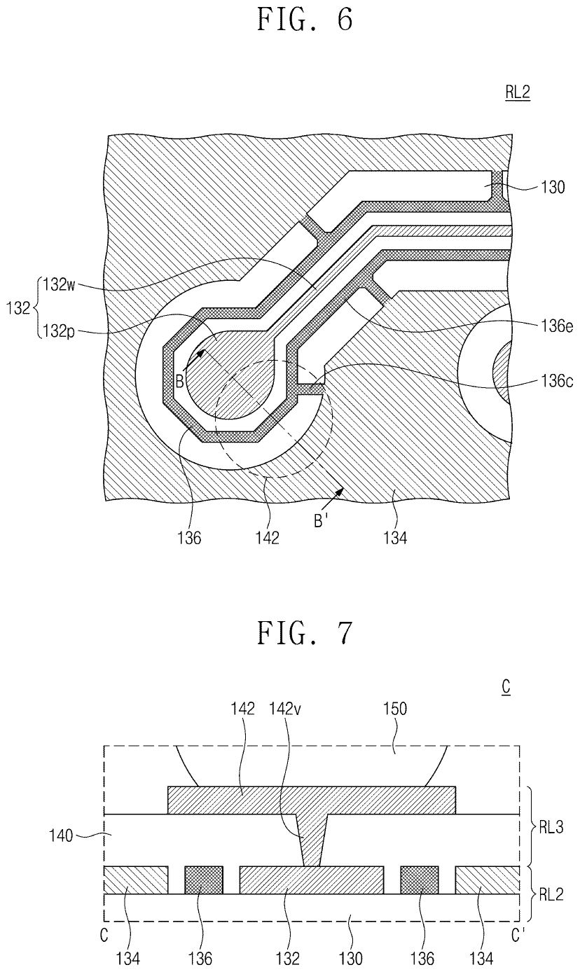

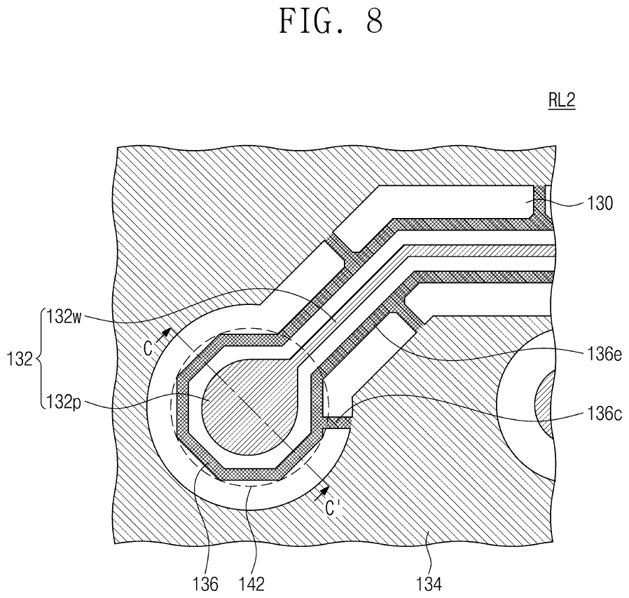

FIG. 1 is a sectional view illustrating a wiring substrate In some implementations. FIG. 2 is an enlarged sectional view illustrating a portion A of FIG. 1. FIGS. 3 and 4 are plan views corresponding to the structure of FIG. 2. FIG. 2 is a sectional view corresponding to a line A-A′ of FIGS. 3 and 4. FIG. 5 is an enlarged sectional view illustrating a portion B of FIG. 1. FIG. 6 is a plan view corresponding to the structure of FIG. 5. FIG. 5 is a sectional view corresponding to a line B-B′ of FIG. 6. FIG. 7 is an enlarged sectional view illustrating a portion C of FIG. 1. FIG. 8 is a plan view corresponding to the structure of FIG. 7. FIG. 7 is a sectional view corresponding to a line C-C′ of FIG. 8.

Referring to FIG. 1, a wiring substrate 100 may be provided. The wiring substrate 100 may have a structure including a plurality of wiring patterns provided in an insulating layer. For example, the wiring substrate 100 may have a structure, in which insulating patterns and wiring patterns are alternately stacked. In detail, the wiring substrate 100 may include two or more wiring layers RL1, RL2, and RL3. FIG. 1 illustrates an example, in which the wiring substrate 100 has three wiring layers RL1, RL2, and RL3. In some implementations, the wiring substrate 100 may have two or four wiring layers, if necessary.

Substrate pads 110 may be provided. The substrate pads 110 may be exposed to a region below a bottom surface of the wiring substrate 100. Although not shown, the substrate pads 110 may have a seed layer or a barrier layer covering bottom and side surfaces of the substrate pads 110. Alternatively, the seed layer or the barrier layer may be provided on only the bottom surfaces of the substrate pads 110.

Referring to FIGS. 1 to 3, a first wiring layer RL1 may be provided. The first wiring layer RL1 may include a first insulating pattern 120 and a first conductive pattern 121.

The first insulating pattern 120 may cover the substrate pads 110. The substrate pads 110 may be placed in the first insulating pattern 120 but may be exposed to a region on a bottom surface of the first insulating pattern 120. The first insulating pattern 120 may include a photoimageable polymer (PID). For example, the photoimageable polymer may include photoimageable polyimides, polybenzoxazole (PBO), phenol-based polymers, and benzocyclobutene-based polymers. Alternatively, the first insulating pattern 120 may include an insulating polymer.

Although not shown, a protection layer may be provided on the bottom surface of the first insulating pattern 120. The protection layer may cover the bottom surface of the first insulating pattern 120 and expose the substrate pads 110. In some implementations, the protection layer may not be provided.

The first conductive pattern 121 may be provided on the first insulating pattern 120. The first conductive pattern 121 on the first insulating pattern 120 may be horizontally extended. For example, the first conductive pattern 121 may be portions (e.g., first wiring portions or first pad portions) of the first wiring layer RL1. In other words, the first conductive pattern 121 may be an element that is used for horizontal redistribution in the wiring substrate 100. The first conductive pattern 121 may be provided on a top surface of the first insulating pattern 120. Unlike the illustrated structure, the first conductive pattern 121 may be provided in an upper portion of the first insulating pattern 120. In this case, a top surface of the first conductive pattern 121 may be exposed to a region on the top surface of the first insulating pattern 120. The first conductive pattern 121 may include a conductive material. For example, the first conductive pattern 121 may be formed of or include copper (Cu).

First vias 121v may be provided below the first conductive pattern 121. The first via 121v may be an element that is used to connect the first conductive pattern 121 of the first wiring layer RL1 to the substrate pads 110. For example, the first vias 121v may be provided on a portion of a bottom surface of the first conductive pattern 121. The first vias 121v may vertically penetrate the first insulating pattern 120 and may be coupled to top surfaces of the substrate pads 110. The first vias 121v may include a conductive material. For example, the first vias 121v may be formed of or include copper (Cu).

The first conductive pattern 121 and the first vias 121v may have a damascene structure. For example, the first conductive pattern 121 and the first vias 121v may form a single object, and here, the first conductive pattern 121 may serve as a head portion of the single object, and the first vias 121v may serve as tail portions of the single object. The first conductive pattern 121 and the first vias 121v may be provided to have no interface therebetween. Here, a portion of the first conductive pattern 121 connected to the first vias 121v may have a width larger than the first vias 121v. The first conductive pattern 121 and the first vias 121v may have a T-shaped structure.

A barrier layer or a seed layer may be interposed between the first insulating pattern 120 and the first conductive pattern 121. The barrier layer or the seed layer may be formed to conformally cover side surfaces of the first conductive pattern 121 and the first vias 121v. In other words, the barrier layer or the seed layer may be provided to enclose the first conductive pattern 121 and the first vias 121v. The barrier layer may be formed of or include at least one of titanium (Ti), tantalum (Ta), titanium nitride (TiN), or tantalum nitride (TaN).

The first conductive pattern 121 may include a first signal pattern 122, a first ground pattern 124, and a first intervening pattern 126. The first signal pattern 122, the first ground pattern 124, and the first intervening pattern 126 may be placed at the same level in a vertical direction. That is, the first signal pattern 122, the first ground pattern 124, and the first intervening pattern 126 may be patterns, which are formed on the first insulating pattern 120 by patterning a single conductive layer.

The first signal pattern 122 may be an input/output pattern, which is used to provide input/output signals to electronic devices mounted on the wiring substrate 100. The first signal pattern 122 may include a first pad pattern 122p and a first wiring pattern 122w. The first pad pattern 122p may be a pad, to which a second via 131v of a second wiring layer RL2 is coupled. The first pad pattern 122p may have a plate-like shape or a planar shape. For example, the first pad pattern 122p may have a circular planar shape. The first wiring pattern 122w may be extended from the first pad pattern 122p. The first wiring pattern 122w may be provided to have a line shape. A width of the first wiring pattern 122w may be smaller than a width of the first pad pattern 122p.

The first ground pattern 124 may be a ground pattern, which is used to apply a ground voltage to the electronic devices mounted on the wiring substrate 100. As shown in FIG. 3, the first ground pattern 124 may be provided on a region of the first wiring layer RL1, in which the first signal pattern 122 is not disposed. When viewed in a plan view, the first ground pattern 124 may enclose the first signal pattern 122. The first ground pattern 124 may be horizontally spaced apart from the first signal pattern 122. For example, the first ground pattern 124 may be provided to define an open hole having a larger planar area than the first signal pattern 122, and the first signal pattern 122 may be disposed in the open hole of the first ground pattern 124. In some implementations, the first ground pattern 124 may be provided to enclose the first pad pattern 122p while being spaced apart from the first pad pattern 122p by a first distance G1 and may be extended from the side surface of the first pad pattern 122p along the side surfaces of the first wiring pattern 122w. The first ground pattern 124 may be extended from bedside of the first pad pattern 122p to bedside of the first wiring pattern 122w.

A distance between the first ground pattern 124 and the first signal pattern 122 may be substantially uniform. In some implementations, the first distance G1 between the first ground pattern 124 and the first pad pattern 122p of the first signal pattern 122 may be substantially uniform. The first distance G1 between the first ground pattern 124 and the first pad pattern 122p may be 5 to 10 times a thickness T1 of the first conductive pattern 121. The first distance G1 between the first ground pattern 124 and the first pad pattern 122p may range from 30 μm to 50 μm. A third distance G3 between the first ground pattern 124 and the first wiring pattern 122w of the first signal pattern 122 may be substantially uniform. The third distance G3 may be substantially equal to the first distance G1. The distance between the patterns of the first conductive pattern 121 and the thickness of the first conductive pattern 121 illustrated in FIGS. 1 to 3 are merely examples.

The first intervening pattern 126 may be disposed between the first signal pattern 122 and the first ground pattern 124. In some implementations, the first intervening pattern 126 may be disposed between the first pad pattern 122p of the first signal pattern 122 and the first ground pattern 124. The first intervening pattern 126 may be horizontally spaced apart from the first signal pattern 122 and the first ground pattern 124. The first intervening pattern 126 may include a plurality of linear patterns that are connected in series. Each of the linear patterns may have a linear shape extending in a respective direction. The linear patterns may be arranged along a side surface (i.e., an outer circumference) of the first pad pattern 122p. For example, the first intervening pattern 126 may have a polygonal ring shape, when viewed in a plan view. In the present specification, an expression “an element has a ring shape in a plan view” should not be interpreted as indicating only a closed ring shape. A portion of the first intervening pattern 126 may have an open shape, when viewed in a plan view. That is, the first intervening pattern 126 may have a partially open polygonal ring shape. The first pad pattern 122p may be placed inside a region, which is confined by the ring-shaped portion of first intervening pattern 126, and the first wiring pattern 122w may be extended to the outside through the open portion of the first intervening pattern 126. FIG. 3 illustrates an example, in which the first intervening pattern 126 is provided to have an octagonal ring shape in a plan view. In some examples, the first intervening pattern 126 may be a polygonal ring that is composed of six or more linear patterns. The linear patterns may be provided to have the same length or different lengths from each other. A second distance G2 between the first intervening pattern 126 and the first pad pattern 122p may be 1 to 3 times the thickness T1 of the first conductive pattern 121. The second distance G2 between the first intervening pattern 126 and the first pad pattern 122p may range from 3 μm to 20 μm. Here, the second distance G2 between the first intervening pattern 126 and the first pad pattern 122p may be the smallest of the distances between one of the linear patterns of the first intervening pattern 126 and the first pad pattern 122p. Each of the linear patterns of the first intervening pattern 126 may be spaced apart from the first pad pattern 122p by the second distance G2.

The first conductive pattern 121 may further include a first connection pattern 126c connecting the first ground pattern 124 to the first intervening pattern 126. The first connection pattern 126c may be extended from the first intervening pattern 126 and may be connected to the first ground pattern 124. The first connection pattern 126c may have a linear shape extending in a respective direction. The first intervening pattern 126 may be grounded through the first connection pattern 126c.

In some implementations, as shown in FIG. 4, the first intervening pattern 126 may include a first extension pattern 126e, which is extended from a region between the first pad pattern 122p of the first signal pattern 122 and the first ground pattern 124 to a region between the first wiring pattern 122w and the first ground pattern 124. The first extension pattern 126e may be horizontally spaced apart from the first signal pattern 122 and the first ground pattern 124. The first extension pattern 126e may be extended along the side surfaces of the first wiring pattern 122w and may have a linear shape. A fourth distance G4 between the first extension pattern 126e and the first wiring pattern 122w may be 1 to 3 times the thickness T1 of the first conductive pattern 121. The fourth distance G4 between the first extension pattern 126e and the first wiring pattern 122w may range from 3 μm to 20 μm.

Referring back to FIGS. 1 to 3, the second wiring layer RL2 may be stacked on the first wiring layer RL1. The second wiring layer RL2 may include a second insulating pattern 130 and a second conductive pattern 131.

The second insulating pattern 130 may be provided on the first insulating pattern 120 to cover the first conductive pattern 121. The second insulating pattern 130 may include a photoimageable polymer (PID). For example, the photoimageable polymer may include at least one of photoimageable polyimides, polybenzoxazole (PBO), phenol-based polymers, and benzocyclobutene-based polymers. Alternatively, the second insulating pattern 130 may be formed of or include an insulating polymer.

The second insulating pattern 130 on the first insulating pattern 120 may cover wires (e.g., the first conductive pattern 121 and so forth) provided in the first wiring layer RL1, and in this case, the second insulating pattern 130 may have an undulated top surface, due to a height difference between the top surface of the first insulating pattern 120 and the wire. For example, the top surface of the second insulating pattern 130 may have a region with a large depth or height difference. In this case, an air gap or a void may be formed during the fabrication process (e.g., the deposition process) of the semiconductor package, or there may be a failure issue (e.g., a delamination issue between the wiring layers RL1 and RL2) in the wiring substrate.

In some implementations, the first intervening pattern 126 may be provided in a region of the first wiring layer RL1 between the first signal pattern 122 and the first ground pattern 124. Thus, it may be possible to reduce the size of a space or gap, which is formed between the wires provided in the first wiring layer RL1, and to suppress an undulation issue in the top surface of the second insulating pattern 130 covering the first signal pattern 122, the first intervening pattern 126, and the first ground pattern 124. Furthermore, the first pad pattern 122p, which has a rounded shape in a plan view, may be spaced apart from the first ground pattern 124, which is placed near the first pad pattern 122p, by a relatively large distance, owing to the process characteristics in the patterning process. However, since the first intervening pattern 126 is provided in a region between the first pad pattern 122p and the first ground pattern 124, it may be possible to reduce the size of the space or gap between the wires in the first wiring layer RL1 and to suppress the undulation issue in the top surface of the second insulating pattern 130 covering the first pad pattern 122p and the first ground pattern 124. That is, the top surface of the second insulating pattern 130 may be provided to have a flatter profile, and this may make it possible to reduce a failure in the fabrication process of the semiconductor package and to prevent the delamination issue between the wiring layers RL1 and RL2. Accordingly, it may be possible to improve the structural stability of the wiring substrate.

Referring back to FIGS. 1 to 3, a first surface 130u1, which is a portion of the top surface of the second insulating pattern 130 and is placed on the first pad pattern 122p, may be a planarization surface having a substantially flat profile. A second surface 130u2, which is a portion of the top surface of the second insulating pattern 130 and is placed on the first ground pattern 124, may be a planarization surface having a substantially flat profile. A third surface 130u3, which is a portion of the top surface of the second insulating pattern 130 and is placed on the first intervening pattern 126, may be a planarization surface having a substantially flat profile. A fourth surfaces 130cv, which is a portion of the top surface of the second insulating pattern 130 and is placed between the first surface 130u1 and the third surface 130u3 or between the second surface 130u2 and the third surface 130u3, may be a concave surface. The fourth surfaces 130cv may be placed between the first pad pattern 122p and the first ground pattern 124, when viewed in a plan view. The fourth surfaces 130cv may connect the first surface 130u1 to the third surface 130u3 or may connect the second surface 130u2 to the third surface 130u3. The fourth surfaces 130cv may have a shape, which is downwardly recessed from the first surface 130u1 and the second surface 130u2. The bottommost end of the fourth surfaces 130cv may be placed at a level higher than the top surface of the first conductive pattern 121. A vertical height difference D from the bottommost end of the fourth surfaces 130cv to the first surface 130u1 or the second surface 130 u2 (e.g., the depth D of the fourth surfaces 130 cv) may be greater than 0 times a vertical height T2 of the second insulating pattern 130 and less than or equal to 0.1 times the vertical height T2. Unlike the structure illustrated in FIG. 2, the top surface of the second insulating pattern 130 may have a substantially flat profile.

The second conductive pattern 131 may be provided on the second insulating pattern 130. The second conductive pattern 131 on the second insulating pattern 130 may be horizontally extended. For example, the second conductive pattern 131 may be portions (e.g., second wiring portions or second pad portions) of the second wiring layer RL2. In other words, the second conductive pattern 131 may be an element that is used for horizontal redistribution in the wiring substrate 100. The second conductive pattern 131 may be provided on the top surface of the second insulating pattern 130. Unlike the illustrated structure, the second conductive pattern 131 may be provided in an upper portion of the second insulating pattern 130. In this case, a top surface of the second conductive pattern 131 may be exposed to a region on the top surface of the second insulating pattern 130. The second conductive pattern 131 may include a conductive material. For example, the second conductive pattern 131 may be formed of or include copper (Cu).

The second vias 131v may be provided below the second conductive pattern 131. The second via 131v may be an element that is used to connect the second conductive pattern 131 of the second wiring layer RL2 to the first conductive pattern 121 of the first wiring layer RL1 (e.g., the first pad pattern 122p). For example, the second via 131v may be provided on a bottom surface of a portion of the second conductive pattern 131. The second vias 131v may vertically penetrate the second insulating pattern 130 and may be coupled to a top surface of the first pad pattern 122p. The second vias 131v may include a conductive material. For example, the second vias 131v may be formed of or include copper (Cu).

The second conductive pattern 131 and the second vias 131v may have a damascene structure. For example, the second conductive pattern 131 and the second vias 131v may form a single object, and here, the second conductive pattern 131 may serve as a head portion of the single object, and the second vias 131v may serve as tail portions of the single object. The second conductive pattern 131 and the second vias 131v may be provided to have no interface therebetween. Here, a portion of the second conductive pattern 131 connected to the second via 131v may have a width that is larger than the width of the second via 131v. The second conductive pattern 131 and the second vias 131v may be provided to form a T-shaped section.

A barrier layer or a seed layer may be interposed between the second insulating pattern 130 and the second conductive pattern 131. The barrier layer or the seed layer may be provided to conformally cover side surfaces of the second conductive pattern 131 and the second vias 131v. That is, the barrier layer or the seed layer may enclose the second conductive pattern 131 and the second vias 131v. The barrier layer may be formed of or include at least one of titanium (Ti), tantalum (Ta), titanium nitride (TiN), or tantalum nitride (TaN).

Referring to FIGS. 1, 5, and 6, the second conductive pattern 131 may include a second signal pattern 132, a second ground pattern 134, and a second intervening pattern 136. The second signal pattern 132, the second ground pattern 134, and the second intervening pattern 136 may be placed at the same level in a vertical direction. That is, the second signal pattern 132, the second ground pattern 134, and the second intervening pattern 136 may be patterns, which are formed by patterning a single conductive layer formed on the second insulating pattern 130.

The second signal pattern 132 may be an input/output pattern, which is used to provide input/output signals to the electronic devices mounted on the wiring substrate 100. The second signal pattern 132 may include a second pad pattern 132p and a second wiring pattern 132w. The second pad pattern 132p may be a pad, to which a third via 142v of a third wiring layer RL3 is coupled. The second pad pattern 132p may have a plate-like or planar shape. For example, the second pad pattern 132p may have a circular planar shape. The second wiring pattern 132w may be extended from the second pad pattern 132p. The second wiring pattern 132w may have a line shape. A width of the second wiring pattern 132w may be smaller than a width of the second pad pattern 132p.

The second ground pattern 134 may be a ground pattern, which is used to apply a ground voltage to the electronic devices mounted on the wiring substrate 100. As shown in FIG. 6, the second ground pattern 134 may be provided on a region of the second wiring layer RL2, in which the second signal pattern 132 is not disposed. When viewed in a plan view, the second ground pattern 134 may enclose the second signal pattern 132. The second ground pattern 134 may be horizontally spaced apart from the second signal pattern 132. That is, the second ground pattern 134 may be provided to define an open hole having a larger planar area than the second signal pattern 132, and the second signal pattern 132 may be disposed in the open hole of the second ground pattern 134. In some implementations, the second ground pattern 134 may be provided to enclose the second pad pattern 132p while being spaced apart from the second pad pattern 132p by a specific distance and may be extended from the side surface of the second pad pattern 132p along the side surfaces of the second wiring pattern 132w. The second ground pattern 134 may be extended from bedside of the second pad pattern 132p to bedside of the second wiring pattern 132w.

A distance between the second ground pattern 134 and the second signal pattern 132 may be substantially uniform. In some implementations, distance between the second ground pattern 134 and the second pad pattern 132p of the second signal pattern 132 may be substantially uniform. The distance between the second ground pattern 134 and the second wiring pattern 132w of the second signal pattern 132 may be substantially uniform. The distance between the second ground pattern 134 and the second pad pattern 132p or the second wiring pattern 132w may be 5 to 10 times the thickness of the second conductive pattern 131. The distance between the second ground pattern 134 and the second pad pattern 132p or between the second ground pattern 134 and the second wiring pattern 132w may range from 30 μm to 50 μm.

The second intervening pattern 136 may be disposed between the second signal pattern 132 and the second ground pattern 134. In some implementations, the second intervening pattern 136 may be disposed between the second pad pattern 132p of the second signal pattern 132 and the second ground pattern 134. The second intervening pattern 136 may be horizontally spaced apart from the second signal pattern 132 and the second ground pattern 134. The second intervening pattern 136 may include a plurality of linear patterns that are connected in series. Each of the linear patterns may have a linear shape extending in a respective direction. The linear patterns may be arranged along a side surface (i.e., an outer circumference) of the second pad pattern 132p. For example, the second intervening pattern 136 may have a polygonal ring shape, when viewed in a plan view. A portion of the second intervening pattern 136 may have an open shape. In other words, the second intervening pattern 136 may have a partially open polygonal ring shape, when viewed in a plan view. The second pad pattern 132p may be placed inside a region, which is confined by the ring-shaped portion of the second intervening pattern 136, and the second wiring pattern 132w may be extended to the outside through the open portion of the second intervening pattern 136. The second intervening pattern 136 may be a polygonal ring that is composed of six or more linear patterns. The linear patterns may be provided to have the same length or different lengths from each other. A distance between the second intervening pattern 136 and the second pad pattern 132p may be 1 to 3 times the thickness of the second conductive pattern 131. The distance between the second intervening pattern 136 and the second pad pattern 132p may range from 3 μm to 20 μm. Each of the linear patterns of the second intervening pattern 136 may be spaced apart from the second pad pattern 132p by a specific distance.

The second conductive pattern 131 may further include a second connection pattern 136c connecting the second ground pattern 134 to the second intervening pattern 136. The second connection pattern 136c may be extended from the second intervening pattern 136 and may be connected to the second ground pattern 134. The second connection pattern 136c may have a linear shape extending in a respective direction. The second intervening pattern 136 may be grounded through the second connection pattern 136c.

The second intervening pattern 136 may include a second extension pattern 136e, which extended from a region between the second pad pattern 132p of the second signal pattern 132 and the second ground pattern 134 to a region between the second wiring pattern 132w and the second ground pattern 134. The second extension pattern 136e may be horizontally spaced apart from the second signal pattern 132 and the second ground pattern 134. The second extension pattern 136e may be extended along the side surfaces of the second wiring pattern 132w and may have a linear shape. A distance between the second extension pattern 136e and the second wiring pattern 132w may be 1 to 3 times the thickness of the second conductive pattern 131. The distance between the second extension pattern 136e and the second wiring pattern 132w may range from 3 μm to 20 μm. The second extension pattern 136e may be provided, if necessary.

The third wiring layer RL3 may be stacked on the second wiring layer RL2. The third wiring layer RL3 may include a third insulating pattern 140 and an under-bump pattern 142.

The third insulating pattern 140 may be provided on the second insulating pattern 130 to cover the second conductive pattern 131. The third insulating pattern 140 may include a photoimageable polymer (PID). For example, the photoimageable polymer may include at least one of photoimageable polyimides, polybenzoxazole (PBO), phenol-based polymers, and benzocyclobutene-based polymers. Alternatively, the third insulating pattern 140 may include an insulating polymer.

The third insulating pattern 140 on the second insulating pattern 130 may cover the wires provided in the second wiring layer RL2, and in this case, a top surface 140u of the third insulating pattern 140 may have an undulation issue, due to a height difference between the top surface of the second insulating pattern 130 and the wires. For example, the top surface 140u of the third insulating pattern 140 may have a region with a large depth or height difference. In this case, an air gap or a void may be formed during the fabrication process (e.g., the deposition process) of the semiconductor package, or there may be a failure issue (e.g., the breakage issue of the under-bump pattern 142 provided on the third insulating pattern 140) in the wiring substrate.

In some implementations, the second intervening pattern 136 may be provided in a region of the second wiring layer RL2 placed between the second signal pattern 132 and the second ground pattern 134. Thus, it may be possible to reduce the size of the space or gap, which is formed between the wires provided in the second wiring layer RL2, and to suppress the undulation issue in the top surface 140u of the third insulating pattern 140 covering the second signal pattern 132, the second intervening pattern 136, and the second ground pattern 134. That is, the top surface 140u of the third insulating pattern 140 may be provided to have a flatter profile, and this may make it possible to reduce a failure in the fabrication process of the semiconductor package and to prevent the breakage issue of the under-bump pattern 142. Accordingly, it may be possible to improve the structural stability of the wiring substrate.

Referring to FIGS. 1, 5, and 6, portions of the top surface 140u of the third insulating pattern 140, which are respectively located on the second pad pattern 132p, the second ground pattern 134, and the second intervening pattern 136, may have a planarization surface having a substantially flat profile. Portions 140cv of the top surface 140u of the third insulating pattern 140, which are placed between the second pad pattern 132p and the first intervening pattern 136 and between the second ground pattern 134 and the second intervening pattern 136 in a plan view, may be a concave surface. The concave surface 140cv of the top surface 140u of the third insulating pattern 140 may be placed between the second pad pattern 132p and the second ground pattern 134, when viewed in a plan view. The concave surface 140cv of the top surface 140u of the third insulating pattern 140 may have a shape, which is downwardly recessed from the top surface 140u of the third insulating pattern 140. The bottommost end of the concave surface 140cv may be placed at a level higher than the top surface of the second conductive pattern 131. A vertical height difference from the bottommost end of the concave surface 140cv to the top surface 140u of the third insulating pattern 140 (i.e., a depth of the concave surface 140cv) may be greater than 0 times a vertical height of the third insulating pattern 140 and may be less than or equal to 0.1 times the vertical height of the third insulating pattern 140. Unlike the structure illustrated in FIG. 5, the top surface of the third insulating pattern 140 may be a planarization surface having a substantially flat profile.

The under-bump pattern 142 may be provided on the third insulating pattern 140. The under-bump pattern 142 may be disposed on the top surface 140u of the third insulating pattern 140. For example, the under-bump pattern 142 may be pads of the wiring substrate 100, on which outer terminals 150 are disposed. The under-bump pattern 142 may include a conductive material. For example, the under-bump pattern 142 may be formed of or include copper (Cu).

The third vias 142v may be provided below the under-bump pattern 142. The third via 142v may be an element that is used to connect the under-bump pattern 142 of the third wiring layer RL3 to the second conductive pattern 131 of the second wiring layer RL2 (e.g., the second pad pattern 132p). For example, the third vias 142v may be provided on a bottom surface of the under-bump pattern 142. The third vias 142v may be provided to vertically penetrate the third insulating pattern 140 and may be coupled to a top surface of the second pad pattern 132p. The third vias 142v may include a conductive material. For example, the third vias 142v may be formed of or include copper (Cu).

The under-bump pattern 142 and the third vias 142v may have a damascene structure. For example, the under-bump pattern 142 and the third vias 142v may form a single object, and here, the under-bump pattern 142 may serve as a head portion of the single object, and the third vias 142v may serve as tail portions of the single object. The under-bump pattern 142 and the third vias 142v may be provided to have no interface therebetween. Here, a width of a portion of the under-bump pattern 142 connected to the third via 142v may be larger than a width of the third via 142v. The under-bump pattern 142 and the third vias 142v may have a T-shaped structure.

A barrier layer or a seed layer may be interposed between the third insulating pattern 140 and the under-bump pattern 142. The barrier layer or the seed layer may conformally cover the side surfaces of the under-bump pattern 142 and the third vias 142v. In other words, the barrier layer or the seed layer may enclose the under-bump pattern 142 and the third vias 142v. The barrier layer may be formed of or include at least one of titanium (Ti), tantalum (Ta), titanium nitride (TiN), or tantalum nitride (TaN).

As shown in FIGS. 5 and 6, the under-bump pattern 142 may be placed on the second pad pattern 132p. The planar area of the under-bump pattern 142 may be larger than the planar area of the second pad pattern 132p. The under-bump pattern 142 may be vertically overlapped with at least a portion of the second pad pattern 132p. When viewed in a plan view, the under-bump pattern 142 may be extended to a region on the second pad pattern 132p to another region next to the second pad pattern 132p. For example, a portion of the under-bump pattern 142 may be extended from a region on the second pad pattern 132p to a region on the second ground pattern 134. The under-bump pattern 142 may be provided to cross a space between the second pad pattern 132p and the second ground pattern 134. In other words, the under-bump pattern 142 may be provided across the concave surface 140cv of the top surface 140u of the third insulating pattern 140 and may cover the concave surface 140cv. The under-bump pattern 142 may cover the second intervening pattern 136, which is provided between the second pad pattern 132p and the second ground pattern 134.

The outer terminals 150 may be disposed on the wiring substrate 100. In detail, the outer terminals 150 may be disposed on the under-bump pattern 142. In other words, the under-bump pattern 142 may be a pattern that is provided on an outer surface of the wiring substrate 100 and is used for connection with the outer terminals 150. FIGS. 1 and 5 illustrate an example, in which the outer terminals 150 are directly connected to the under-bump pattern 142. In some examples, additional pads may be provided on the under-bump pattern 142, and the outer terminals 150 may be coupled to the additional pads. The outer terminals 150 may include solder balls or solder bumps, and according to the type or arrangement of the outer terminals 150, the wiring substrate 100 may be classified into various types, such as ball grid array (BGA), fine ball-grid array (FBGA), or land grid array (LGA).

A strong pressure may be exerted on the under-bump pattern 142, when the outer terminals 150 are attached to the under-bump pattern 142 or the wiring substrate 100 is mounted on another device using the outer terminals 150. In particular, in the space between the patterns of the second conductive pattern 131, the ability to support the under-bump pattern 142 may be weakened. The larger the distance between the patterns of the second conductive pattern 131, the weaker the ability to support the under-bump pattern 142, and in this case, the breakage issue of the under-bump pattern 142 may occur.

In some implementations, if the under-bump pattern 142 is provided to cover both the second pad pattern 132p and the second ground pattern 134, the ability to support the under-bump pattern 142 may be weakened in a space between the second pad pattern 132p and the second ground pattern 134. Since the second intervening pattern 136 is provided between the second pad pattern 132p and the second ground pattern 134, the second intervening pattern 136 may be spaced apart from the second pad pattern 132p or the second ground pattern 134 by a small distance, and thus, the under-bump pattern 142 in the space between the second pad pattern 132p and the second ground pattern 134 may be more robustly supported by the second intervening pattern 136. Accordingly, it may be possible to prevent or suppress the under-bump pattern 142 from being broken and improve the structural stability of the wiring substrate 100.

FIGS. 5 and 6 illustrate the under-bump pattern 142 covering the second pad pattern 132p of the second signal pattern 132.

Referring to FIGS. 1, 7, and 8, the under-bump pattern 142 may be placed on the second pad pattern 132p. The planar area of the under-bump pattern 142 may be larger than the planar area of the second pad pattern 132p. The under-bump pattern 142 may be vertically overlapped with at least a portion of the second pad pattern 132p. The under-bump pattern 142 may be vertically overlapped with a portion of the second wiring pattern 132w connected to the second pad pattern 132p. When viewed in a plan view, the under-bump pattern 142 may be extended to beside of the second wiring pattern 132w above the second pad pattern 132p. In some implementations, a side surface of the under-bump pattern 142 may be placed on a portion of the second wiring pattern 132w connected to the second pad pattern 132p.

The under-bump pattern 142 may cover the second intervening pattern 136. In more detail, the under-bump pattern 142 may cover the second intervening pattern 136 enclosing the second pad pattern 132p and may cover a portion of the second extension pattern 136e located next to the second wiring pattern 132w.

A strong pressure may be exerted on the under-bump pattern 142, when the outer terminals 150 are attached to the under-bump pattern 142 or the wiring substrate 100 is mounted on another device using the outer terminals 150. In particular, a strong stress may be exerted on a portion below an edge of the under-bump pattern 142 (e.g., the side surface of the under-bump pattern 142). In this case, the second wiring pattern 132w, which has a smaller width than the second pad pattern 132p, may be easily broken by the stress.

In some implementations, the second intervening pattern 136 may be provided near or around the second wiring pattern 132w, a stress, which is exerted by the under-bump pattern 142, may be alleviated by the second wiring pattern 132w and the second intervening pattern 136. As a result, it may be possible to prevent or suppress the second wiring pattern 132w from being broken by the under-bump pattern 142 and improve the structural stability of the wiring substrate 100.

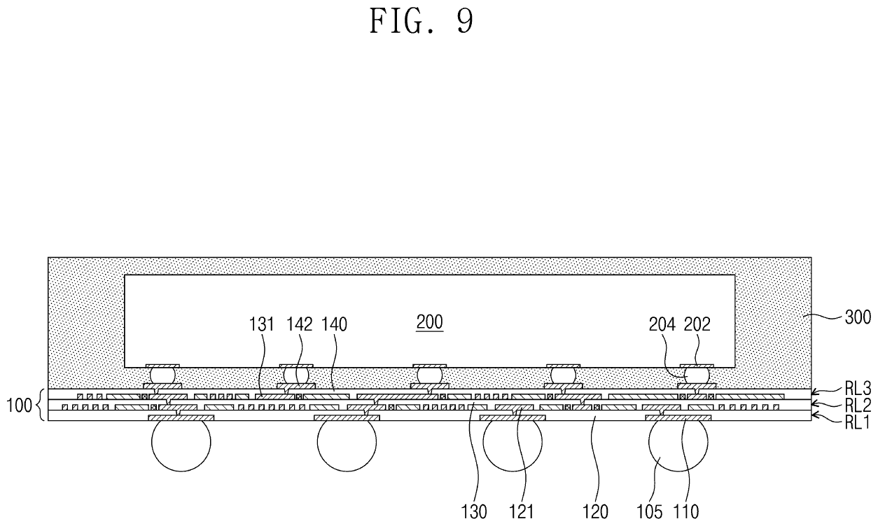

FIG. 9 is a sectional view illustrating a semiconductor package In some implementations.

Referring to FIG. 9, the wiring substrate 100 may be provided. The wiring substrate 100 may be substantially the same or similar to the wiring substrate 100 described with reference to FIGS. 1 to 8. For example, the wiring substrate 100 may include two or more wiring layers RL1, RL2, and RL3.

The substrate pads 110 may be provided. The first insulating pattern 120 of the first wiring layer RL1 may cover the substrate pads 110. The first conductive pattern 121 of the first wiring layer RL1 may be provided on the first insulating pattern 120. The first conductive pattern 121 may be coupled to the substrate pads 110 through the first vias. The first conductive pattern 121 may have the first signal pattern 122 of FIG. 1, the first ground pattern 124 of FIG. 1, and the first intervening pattern 126 of FIG. 1. The first intervening pattern may be provided between the first pad pattern of the first signal pattern and the first ground pattern. The first intervening pattern may have a partially open polygonal ring shape, when viewed in a plan view.

The second insulating pattern 130 of the second wiring layer RL2 may cover the first conductive pattern 121, on the first insulating pattern 120 of the first wiring layer RL1. The second conductive pattern 131 of the second wiring layer RL2 may be provided on the second insulating pattern 130. The second conductive pattern 131 may be coupled to the first pad pattern of the first conductive pattern 121 through the second vias. The second conductive pattern 131 may have the second signal pattern 132 of FIG. 1, the second ground pattern 134 of FIG. 1, and the second intervening pattern 136 of FIG. 1. The second intervening pattern may be provided between the second pad pattern of the second signal pattern and the second ground pattern. The second intervening pattern may have a partially open polygonal ring shape, when viewed in a plan view.

The third insulating pattern 140 of the third wiring layer RL3 may be provided on the second insulating pattern 130 of the second wiring layer RL2 to cover the second conductive pattern 131. The under-bump pattern 142 of the third wiring layer RL3 may be provided on the third insulating pattern 140. The under-bump pattern 142 may be coupled to the second pad pattern of the second conductive pattern 131 through the third vias.

Substrate terminals 105 may be disposed below the wiring substrate 100. In detail, the substrate terminals 105 may be disposed on the substrate pads 110, which are disposed on the bottom surface of the wiring substrate 100. The substrate terminals 105 may include solder balls or solder bumps, and according to the type and arrangement of the substrate terminals 105, the semiconductor package may be classified into various types, such as ball grid array (BGA), fine ball-grid array (FBGA), or land grid array (LGA).

A semiconductor chip 200 may be disposed on the wiring substrate 100. The semiconductor chip 200 may include a semiconductor material (e.g., silicon (Si)). The semiconductor chip 200 may include an integrated circuit formed on a surface thereof. The integrated circuit of the semiconductor chip 200 may include a logic circuit or a memory circuit. In other words, the semiconductor chip 200 may be a logic chip or a memory chip. A bottom surface of the semiconductor chip 200 may be an active surface, and a top surface of the semiconductor chip 200 may be an inactive surface. Chip pads 202 may be disposed on the bottom surface of the semiconductor chip 200, and chip terminals 204 may be provided on the chip pads 202. The chip terminals 204 may be electrically connected to the integrated circuit of the semiconductor chip 200.

The semiconductor chip 200 may be mounted on the wiring substrate 100. For example, the semiconductor chip 200 may be mounted on the wiring substrate 100 in a flip-chip manner. The semiconductor chip 200 may be coupled to the under-bump pattern 142 of the wiring substrate 100 through the chip terminals 204. The chip terminals 204 may be provided between the under-bump pattern 142 of the wiring substrate 100 and the chip pads 202.

Although not shown, an under-fill layer may be provided between the wiring substrate 100 and the semiconductor chip 200. The under-fill layer may fill a space between the wiring substrate 100 and the semiconductor chip 200 and may enclose the chip terminals 204.

A mold layer 300 may be provided on the wiring substrate 100. The mold layer 300 may cover a top surface of the wiring substrate 100. The mold layer 300 may enclose the semiconductor chip 200. The mold layer 300 may include an insulating material. For example, the mold layer 300 may be formed of or include an epoxy molding compound (EMC)

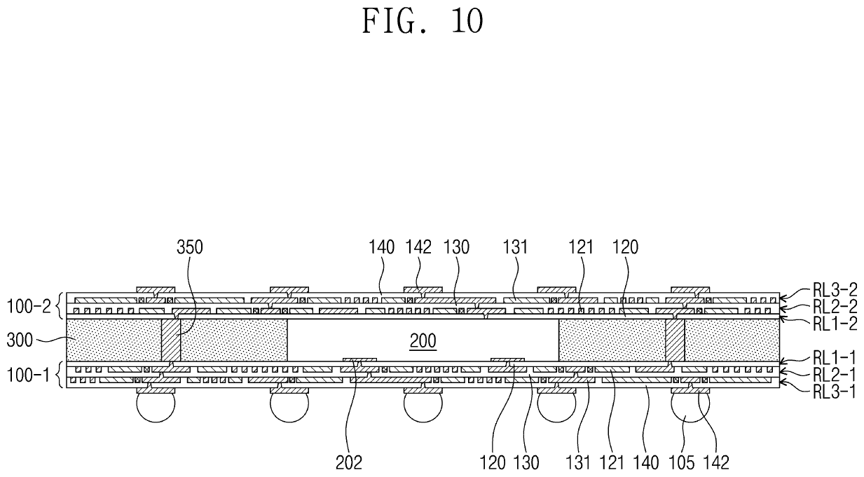

FIG. 10 is a sectional view illustrating a semiconductor package In some implementations.

Referring to FIG. 10, the semiconductor chip 200 may be disposed. The semiconductor chip 200 may include an integrated circuit formed on a surface thereof. The integrated circuit of the semiconductor chip 200 may include a logic circuit or a memory circuit. The bottom surface of the semiconductor chip 200 may be an active surface, and the top surface of the semiconductor chip 200 may be an inactive surface. The chip pads 202 may be disposed on the bottom surface of the semiconductor chip 200. Bottom surfaces of the chip pads 202 may be coplanar with the bottom surface of the semiconductor chip 200.

The mold layer 300 may be provided to enclose the semiconductor chip 200. The top surface of the semiconductor chip 200 may be exposed to a region on a top surface of the mold layer 300. The top surface of the semiconductor chip 200 and the top surface of the mold layer 300 may be substantially coplanar with each other. Alternatively, the mold layer 300 may cover the top surface of the semiconductor chip 200. The bottom surface of the semiconductor chip 200 may be exposed to a region on a bottom surface of the mold layer 300. The bottom surface of the semiconductor chip 200 and the bottom surface of the mold layer 300 may be substantially coplanar with each other.

Conductive posts 350 may be disposed near or around the semiconductor chip 200. The conductive posts 350 may be provided to vertically penetrate the mold layer 300. Top surfaces of the conductive posts 350 may be exposed to a region on the top surface of the mold layer 300. The top surface of the conductive posts 350 and the top surface of the mold layer 300 may be substantially coplanar with each other. Bottom surfaces of the conductive posts 350 may be exposed to a region on the bottom surface of the mold layer 300. The bottom surfaces of the conductive posts 350 and the bottom surface of the mold layer 300 may be substantially coplanar with each other.

A first wiring substrate 100-1 may be disposed below the semiconductor chip 200 and the mold layer 300. The first wiring substrate 100-1 may be substantially the same as or similar to the wiring substrate 100 described with reference to FIGS. 1 to 8. For example, the first wiring substrate 100-1 may include two or more wiring layers RL1-1, RL2-1, and RL3-1.

The first insulating pattern 120 of the first wiring layer RL1-1 may cover the bottom surface of the semiconductor chip 200, the bottom surfaces of the conductive posts 350, and the bottom surface of the mold layer 300. The first conductive pattern 121 of the first wiring layer RL1-1 may be provided on the first insulating pattern 120. The first conductive pattern 121 may be coupled to the chip pads 202 and the conductive posts 350 through the first vias. The first conductive pattern 121 may have a first signal pattern, a first ground pattern, and a first intervening pattern. The first intervening pattern may be provided between the first pad pattern of the first signal pattern and the first ground pattern.

The second insulating pattern 130 of the second wiring layer RL2-1 may be provided on a bottom surface of the first insulating pattern 120 of the first wiring layer RL1-1 to cover the first conductive pattern 121. The second conductive pattern 131 of the second wiring layer RL2-1 may be provided on the second insulating pattern 130. The second conductive pattern 131 may be coupled to the first pad pattern of the first conductive pattern 121 through the second vias. The second conductive pattern 131 may have a second signal pattern, a second ground pattern, and a second intervening pattern. The second intervening pattern may be provided between the second pad pattern of the second signal pattern and the second ground pattern.

The third insulating pattern 140 of the third wiring layer RL3-1 may be provided on a bottom surface of the second insulating pattern 130 of the second wiring layer RL2-1 to cover the second conductive pattern 131. The under-bump pattern 142 of the third wiring layer RL3-1 may be provided on the third insulating pattern 140. The under-bump pattern 142 may be coupled to the second pad pattern of the second conductive pattern 131 through the third vias.

The substrate terminals 105 may be disposed below the first wiring substrate 100-1. In detail, the substrate terminals 105 may be disposed on the under-bump pattern 142 of the first wiring substrate 100-1.

A second wiring substrate 100-2 may be disposed on the semiconductor chip 200 and the mold layer 300. The second wiring substrate 100-2 may be substantially the same as or similar to the wiring substrate 100 described with reference to FIGS. 1 to 8. For example, the second wiring substrate 100-2 may include two or more wiring layers RL1-2, RL2-2, and RL3-2.

The first insulating pattern 120 of the first wiring layer RL1-2 may cover the top surface of the semiconductor chip 200, the top surface of the conductive posts 350, and the top surface of the mold layer 300. The first conductive pattern 121 of the first wiring layer RL1-2 may be provided on the first insulating pattern 120. The first conductive pattern 121 may be coupled to the conductive posts 350 through the first vias. The first conductive pattern 121 may have a first signal pattern, a first ground pattern, and a first intervening pattern. The first intervening pattern may be provided between the first pad pattern of the first signal pattern and the first ground pattern.

The second insulating pattern 130 of the second wiring layer RL2-2 may be provided on a bottom surface of the first insulating pattern 120 of the first wiring layer RL1-2 to cover the first conductive pattern 121. The second conductive pattern 131 of the second wiring layer RL2-2 may be provided on the second insulating pattern 130. The second conductive pattern 131 may be coupled to the first pad pattern of the first conductive pattern 121 through the second vias. The second conductive pattern 131 may have a second signal pattern, a second ground pattern, and a second intervening pattern. The second intervening pattern may be provided between the second pad pattern of the second signal pattern and the second ground pattern.

The third insulating pattern 140 of the third wiring layer RL3-2 may be provided on a bottom surface of the second insulating pattern 130 of the second wiring layer RL2-2 to cover the second conductive pattern 131. The under-bump pattern 142 of the third wiring layer RL3-2 may be provided on the third insulating pattern 140. The under-bump pattern 142 may be coupled to the second pad pattern of the second conductive pattern 131 through the third vias.

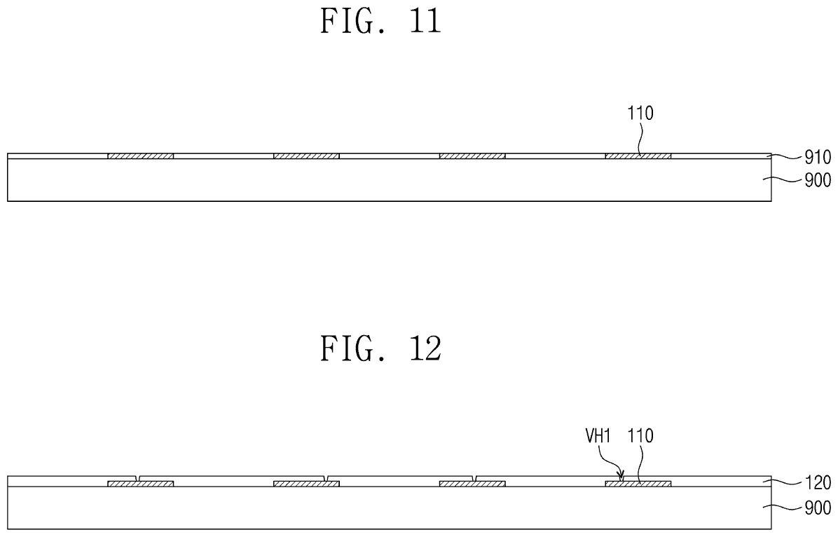

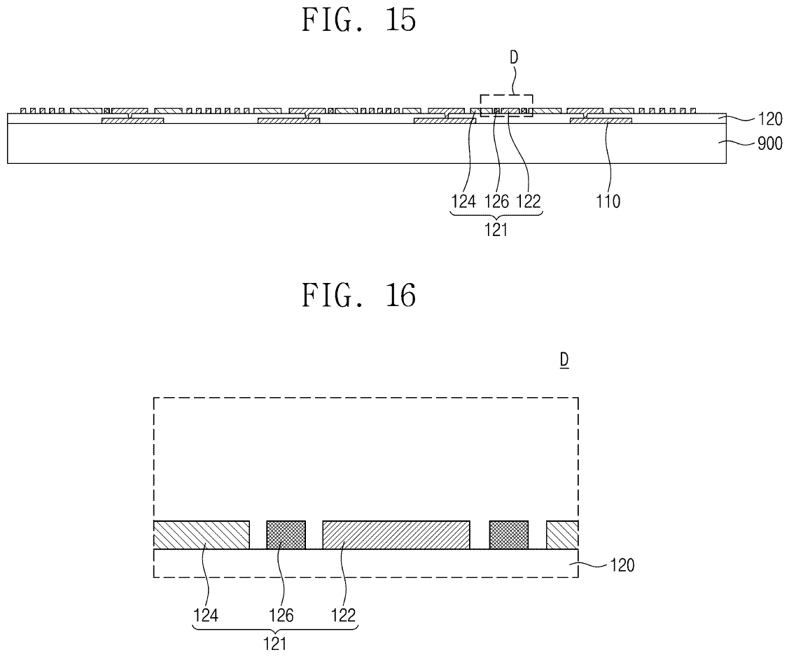

FIGS. 11 to 24 are diagrams illustrating a method of fabricating a wiring substrate In some implementations. FIGS. 11 to 13, 15, 17, 19, 21, and 23 are sectional views illustrating the fabrication method off the wiring substrate, and FIGS. 16, 18, 20, 22, and 24 are enlarged sectional views illustrating portions D of FIGS. 15, 17, 19, 21, and 23.

Referring to FIG. 11, a carrier substrate 900 may be provided. The carrier substrate 900 may be an insulating substrate, which contains glass or polymer, or a conductive substrate, which contains a metallic material. An adhesive member (not shown) may be provided on a top surface of the carrier substrate 900. In some implementations, the adhesive member may include an adhesive tape.

The substrate pads 110 may be formed on the carrier substrate 900. For example, the formation of the substrate pads 110 may include forming a sacrificial layer 910 on the carrier substrate 900, forming openings, in which the substrate pads 110 will be formed, in the sacrificial layer 910, and filling the openings with a conductive material. Alternatively, the formation of the substrate pads 110 may include forming a conductive layer on the carrier substrate 900 and patterning the conductive layer.

Thereafter, the sacrificial layer 910 may be removed.

Referring to FIG. 12, the first insulating pattern 120 may be formed on the carrier substrate 900. For example, an insulating layer may be formed on the carrier substrate 900 to cover the substrate pads 110 and may be patterned to form the first insulating pattern 120. As a result of the patterning process, first via holes VH1 may be formed to expose the substrate pads 110. The first via holes VH1 may be used to define regions, in which the first vias of the first conductive pattern will be formed in a subsequent process. The patterning process may include a process of etching the insulating layer or a process of exposing and developing the insulating layer.

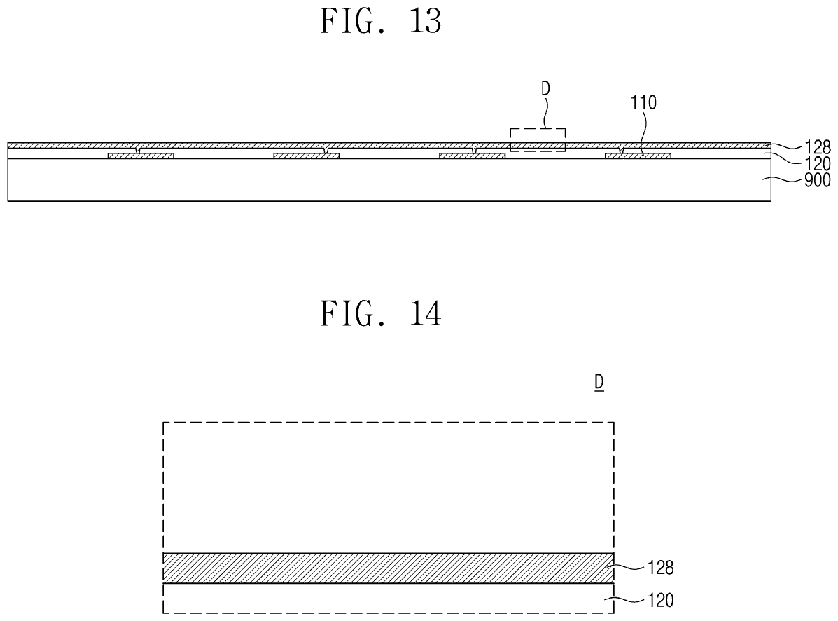

Referring to FIGS. 13 and 14, a first preliminary conductive layer 128 may be formed on the first insulating pattern 120. For example, the formation of the first preliminary conductive layer 128 may include forming a seed layer on the first insulating pattern 120 and performing a plating process using the seed layer as a seed. The first preliminary conductive layer 128 may cover the top surface of the first insulating pattern 120 and may fill the first via holes VH1 of FIG. 12.

Referring to FIGS. 15 and 16, the first conductive pattern 121 may be formed by patterning the first preliminary conductive layer 128. For example, the formation of the first conductive pattern 121 may include forming a mask layer on the first preliminary conductive layer 128 and performing an etching process, in which the mask layer is used as an etch mask, on the first preliminary conductive layer 128.

The first conductive pattern 121 may include or have the first signal pattern 122, the first ground pattern 124, and the first intervening pattern 126. The first signal pattern 122 may include a first pad pattern, which has a circular planar shape, and a first wiring pattern, which is extended from the first pad pattern. The first ground pattern 124 may be formed on a region, in which the first signal pattern 122 is not provided, and may be formed to enclose the first signal pattern 122, when viewed in a plan view. The first intervening pattern 126 may be formed between the first signal pattern 122 and the first ground pattern 124 (e.g., between the first pad pattern of the first signal pattern 122 and the first ground pattern 124). The first intervening pattern 126 may include a plurality of linear patterns that are connected in series. Each of the linear patterns may have a linear shape extending in a respective direction. The linear patterns may be arranged along a side surface (i.e., an outer circumference) of the first pad pattern 122p. For example, the first intervening pattern 126 may have a polygonal ring shape, when viewed in a plan view. A portion of the first intervening pattern 126 may be an open shape.

According to the shape of the first pad pattern of the first signal pattern 122, an edge portion of the first pad pattern may have a rounded shape, as described with reference to FIGS. 3 and 4. In addition, an edge portion of the first ground pattern 124 adjacent to the first pad pattern may have a concave shape corresponding to the edge portion of the first pad pattern. Thus, the mask layer, which is used for a patterning process on the first preliminary conductive layer 128, may have a mask pattern of a rounded shape, on the first pad pattern. If an etching process is performed using the rounded mask pattern, the etching process may have an increased process error, when compared to an etching process performed using a linear mask pattern. For example, for the etching process using the rounded mask pattern, there may be a large difference in the planar shape between the mask pattern and the first conductive pattern 121 formed after the process. Here, to prevent an undesired connection between the patterns of the first conductive pattern 121 (e.g., the first signal pattern 122 and the first ground pattern 124) to be formed, the first signal pattern 122 and the first ground pattern 124 may be spaced apart from each other by a large distance.

In some implementations, the first intervening pattern 126, which is composed of a plurality of linear patterns, may be formed between the first signal pattern 122 and the first ground pattern 124. If the linear mask pattern is used for the etching process, the process error in the etching process may be reduced, and in this case, the first intervening pattern 126 and the first signal pattern 122 may be formed to have a reduced distance therebetween.

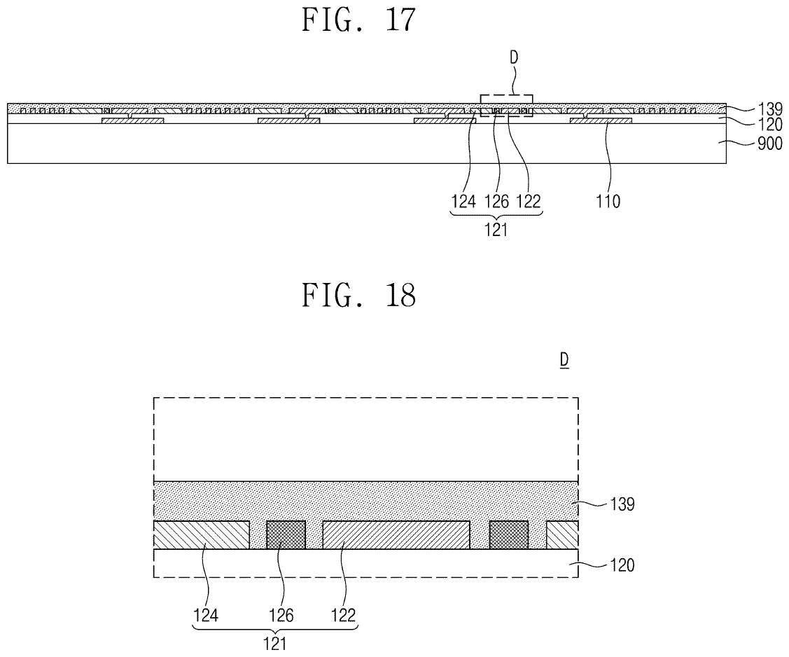

Referring to FIGS. 17 and 18, a preliminary insulating layer 139 may be formed on the first insulating pattern 120. For example, the preliminary insulating layer 139 may be formed on the first insulating pattern 120 to cover the first conductive pattern 121. The preliminary insulating layer 139 may include photoimageable polymer (PID). For example, the photoimageable polymers may include at least one of photoimageable polyimide (PI), polybenzoxazole (PBO), phenol-based polymers, or benzocyclobutene-based polymers. In some implementations, the preliminary insulating layer 139 may include an insulating polymer or an insulating material. For example, the preliminary insulating layer 139 may be formed of or include at least one of silicon oxide (SiO), silicon nitride (SiN), or silicon oxynitride (SiON). A top surface of the preliminary insulating layer 139 may be substantially flat.

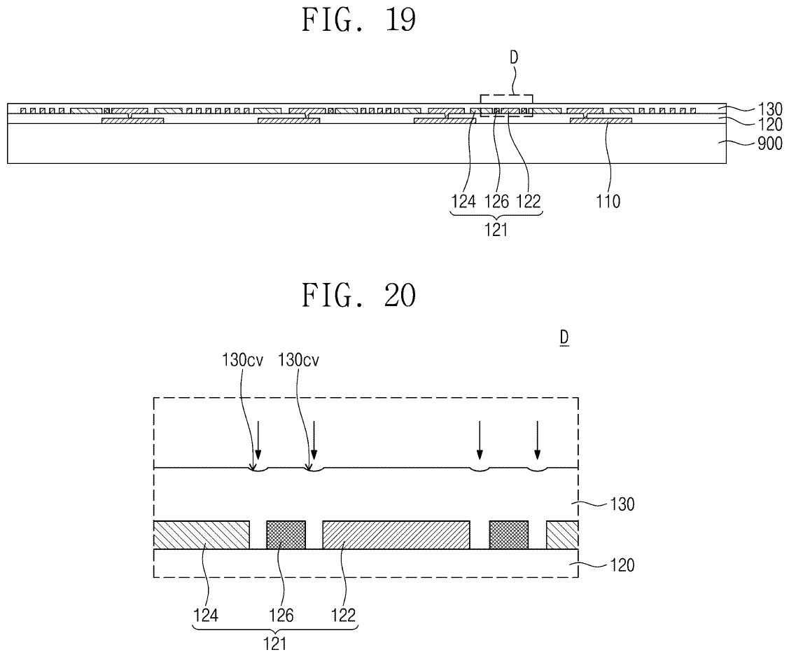

Referring to FIGS. 19 and 20, the second insulating pattern 130 may be formed by curing the preliminary insulating layer 139. For example, the curing process on the preliminary insulating layer 139 may include an optical curing process or a thermal curing process. If necessary, a process of patterning the preliminary insulating layer 139 may be performed, before or after the curing process on the preliminary insulating layer 139. In some implementations, the patterning process may include a process of etching the preliminary insulating layer 139 or a process of exposing and developing the preliminary insulating layer 139.

The volume of the preliminary insulating layer 139 may be reduced during the curing process on the preliminary insulating layer 139. Since the preliminary insulating layer 139 is formed on the first insulating pattern 120 to cover the first conductive pattern 121, the vertical thickness of the preliminary insulating layer 139 on the patterns of the first conductive pattern 121 may differ from the vertical thickness of the preliminary insulating layer 139 between the patterns of the first conductive pattern 121. Thus, a volume change (e.g., a change in thickness) of the preliminary insulating layer 139 may be larger between the patterns of the first conductive pattern 121 than on the first conductive pattern 121. For example, as shown in FIG. 20, the top surface of the second insulating pattern 130 may be lowered between the first signal pattern 122 and the first intervening pattern 126 and between the first intervening pattern 126 and the first ground pattern 124 to form the concave surfaces 130cv.

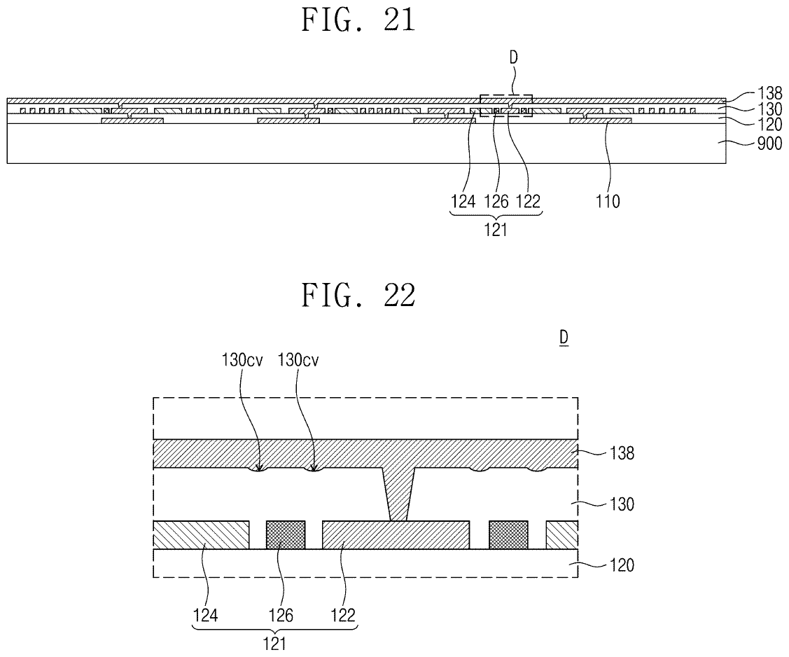

Referring to FIGS. 21 and 22, a second preliminary conductive layer 138 may be formed on the second insulating pattern 130. For example, the formation of the second preliminary conductive layer 138 may include forming a seed layer on the second insulating pattern 130 and performing a plating process using the seed layer as a seed. The second preliminary conductive layer 138 may be provided to conformally cover the top surface of the first insulating pattern 120 and the concave surfaces 130cv.

In some implementations, it may be possible to reduce the distance between the first intervening pattern 126 and the first signal pattern 122 and to reduce the depth of the concave surfaces 130cv of the second insulating pattern 130. This may make it possible to reduce the delamination and breakage issues in the second preliminary conductive layer 138, which is formed on the second insulating pattern 130 in a subsequent process, and to reduce a failure in a process of fabricating the wiring substrate.

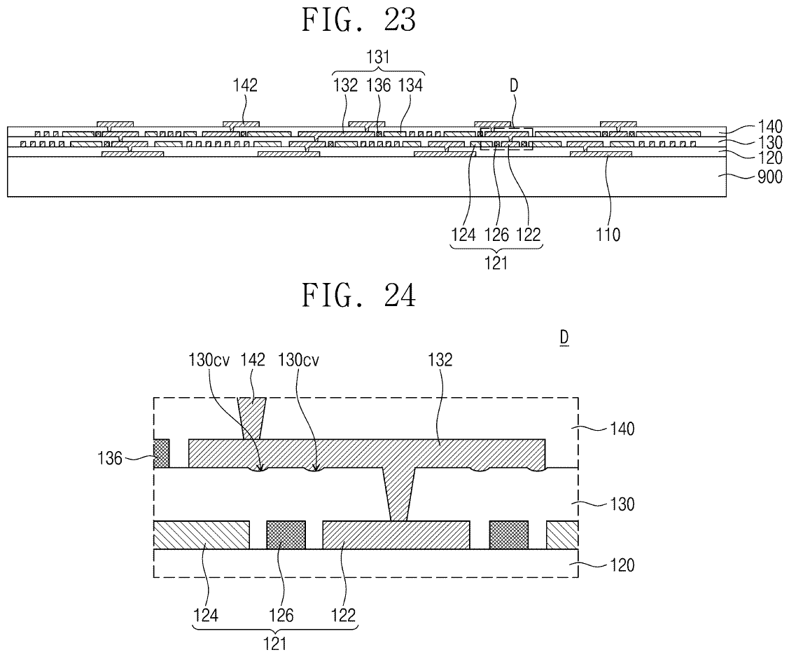

Referring to FIGS. 23 and 24, the second conductive pattern 131 may be formed by patterning the second preliminary conductive layer 138. For example, a mask layer may be formed on the second preliminary conductive layer 138, and then, an etching process using the mask layer as an etch mask may be performed on the second preliminary conductive layer 138 to form the second conductive pattern 131. The second conductive pattern 131 may be placed on at least a portion of the concave surfaces 130cv.

The second conductive pattern 131 may have the second signal pattern 132, the second ground pattern 134, and the second intervening pattern 136. The second signal pattern 132 may have a second pad pattern and a second wiring pattern, which is extended from the second pad pattern. The second ground pattern 134 may be formed on a region, in which the second signal pattern 132 is not provided, and may be formed to enclose the second signal pattern 132, when viewed in a plan view. The second intervening pattern 136 may be formed between the second signal pattern 132 and the second ground pattern 134. The second intervening pattern 136 may include a plurality of linear patterns that are connected in series.

The third insulating pattern 140 may be formed on the second insulating pattern 130. The third insulating pattern 140 may be formed on the second insulating pattern 130 to cover the second conductive pattern 131. The third insulating pattern 140 may be formed in the same or similar method as the process of forming the second insulating pattern 130 described with reference to FIGS. 17 to 20.

The under-bump pattern 142 may be formed on the third insulating pattern 140. For example, the formation of the under-bump pattern 142 may include forming a seed layer on the third insulating pattern 140, forming a preliminary conductive layer by a plating process using the seed layer as a seed, and patterning the preliminary conductive layer.

Referring back to FIG. 1, the carrier substrate 900 may be removed. Thereafter, the outer terminals 150 may be placed on and bonded to the under-bump pattern 142.

In some implementations, a wiring substrate may include an intervening pattern, which is provided in wiring layers and is placed in a region between a signal pattern and a ground pattern. Thus, it may be possible to reduce a space or gap between the wires in the wiring layers and suppress an undulation issue in a top surface of an insulating pattern covering the signal pattern, the intervening pattern, and the ground pattern. In other words, the insulating pattern may be provided to have a highly flat top surface, and this may make it possible to reduce a failure in the fabrication process of the semiconductor package and prevent a delamination issue between the wiring layers. As a result, the wiring substrate may have improved structural stability.

In addition, since the intervening pattern is provided between the pad pattern and the ground pattern, an under-bump pattern between the pad pattern and the ground pattern may be more robustly supported by the intervening pattern. That is, it may be possible to reduce a breakage issue in the under-bump pattern. The intervening pattern may be provided near a wiring pattern that is extended from the pad pattern, and a stress, which is exerted by the under-bump pattern, may be alleviated by the wiring pattern and the intervening pattern. As a result, it may be possible to prevent or suppress the wiring pattern from being broken by the under-bump pattern and improve the structural stability of the wiring substrate.

In general, in some aspects, the present disclosure provides a method of fabricating a wiring substrate. The method may include forming a first insulating pattern on a carrier substrate; forming a first conductive pattern on the first insulating pattern; forming a second insulating pattern on the first insulating pattern to cover the first conductive pattern; and forming a second conductive pattern on the second insulating pattern. The formation of the first conductive pattern may include forming a first conductive layer on the first insulating pattern and patterning the first conductive layer to form a pad pattern, a wiring pattern, a ground pattern, and an intervening pattern. The wiring pattern may be extended from the pad pattern. The ground pattern may enclose the pad pattern. The intervening pattern may be placed between the pad pattern and the ground pattern. The formation of the second insulating pattern may include forming a preliminary insulating layer on the first insulating pattern to cover the first conductive pattern and curing the preliminary insulating layer. During the curing of the preliminary insulating layer, a top surface of the second insulating pattern may be lowered between the pad pattern and the intervening pattern to form a concave surface. The bottommost end of the concave surface may be located at a level higher than a top surface of the first conductive pattern.

In some implementations, the intervening pattern may include a plurality of linear patterns connected in series.

In some implementations, the intervening pattern may have a partially open polygonal ring shape, when viewed in a plan view.

In some implementations, a first distance between the pad pattern and the ground pattern may be substantially uniform.

In some implementations, the first distance between the pad pattern and the ground pattern may be 5 to 10 times a thickness of the first conductive pattern.

In some implementations, a depth of the concave surface may be greater than 0 times a vertical height of the second insulating pattern and less than or equal to 0.1 times the vertical height of the second insulating pattern.

In some implementations, the formation of the second conductive pattern may include forming a second conductive layer on the second insulating pattern and patterning the second conductive layer to form the second conductive pattern. The second conductive layer may conformally cover the concave surface.

In some implementations, the second conductive pattern may be placed on the concave surface.

In some implementations, the ground pattern may be extended from a region facing the pad pattern to another region facing the wiring pattern. A second distance between the ground pattern and the wiring pattern may be substantially uniform. The intervening pattern may be extended into a region between the ground pattern and the wiring pattern.

In some implementations, the second distance may be substantially equal to the first distance between the pad pattern and the ground pattern.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. While example implementations of the inventive concept have been particularly shown and described, it will be understood by one of ordinary skill in the art that variations in form and detail may be made therein without departing from the spirit and scope of the attached claims.

What is claimed is:

1. A wiring substrate comprising:
a first wiring layer; and
a second wiring layer on the first wiring layer,
wherein the first wiring layer comprises
a first insulating pattern, and
a first conductive pattern on the first insulating pattern,
wherein the second wiring layer comprises
a second insulating pattern on the first insulating pattern and covering the first conductive pattern, and
a second conductive pattern on the second insulating pattern,
wherein the first conductive pattern comprises
a pad pattern and a wiring pattern extended from the pad pattern,
a ground pattern enclosing the pad pattern in a plan view, and
an intervening pattern between the pad pattern and the ground pattern,
wherein the intervening pattern is spaced apart from the pad pattern and the ground pattern,
wherein a first distance between the pad pattern and the ground pattern is substantially uniform, and
wherein the intervening pattern comprises a plurality of linear patterns connected in series.

2. The wiring substrate of claim 1, wherein the intervening pattern has a partially open polygonal ring shape in a plan view.

3. The wiring substrate of claim 1, wherein the first distance between the pad pattern and the ground pattern is 5 to 10 times a thickness of the first conductive pattern.

4. The wiring substrate of claim 3, wherein the first distance between the pad pattern and the ground pattern ranges from 30 micrometers (μm) to 50 μm.

5. The wiring substrate of claim 1, wherein a second distance between the pad pattern and the intervening pattern is 1 to 3 times a thickness of the first conductive pattern.

6. The wiring substrate of claim 5, wherein the second distance between the pad pattern and the intervening pattern ranges from 3 micrometers (μm) to 20 μm.

7. The wiring substrate of claim 1, wherein the first conductive pattern comprises a connection pattern connecting the ground pattern to the intervening pattern.

8. The wiring substrate of claim 1, wherein the ground pattern is extended from a side of the pad pattern to a side of the wiring pattern,
wherein a third distance between the ground pattern and the wiring pattern is uniform, and
wherein the intervening pattern extends into a region between the ground pattern and the wiring pattern.

9. The wiring substrate of claim 8, wherein the third distance is substantially equal to the first distance.

10. The wiring substrate of claim 8, wherein the second conductive pattern comprises an under-bump pattern that is on the pad pattern and that is coupled with an outer terminal, and
wherein a side surface of the under-bump pattern is on (i) a portion of the wiring pattern, the wiring pattern being in contact with the pad pattern, and (ii) a portion of the intervening pattern, the intervening pattern being adjacent to the wiring pattern.

11. The wiring substrate of claim 1, wherein a top surface of the second insulating pattern comprises:
a first surface on the pad pattern;
a second surface on the ground pattern; and
a third surface between the pad pattern and the ground pattern and connecting the first surface to the second surface,
wherein each of the first surface and the second surface is a planar surface having a substantially flat profile,
wherein the third surface is a concave surface that is downwardly recessed from the first surface and the second surface, and
wherein a bottommost end of the third surface is at a level higher than a top surface of the first conductive pattern.

12. The wiring substrate of claim 11, wherein a vertical height difference from the bottommost end of the third surface to each of the first surface and the second surface is greater than 0 and less than or equal to 0.1 times a vertical height of the second insulating pattern.

13. The wiring substrate of claim 1, wherein a top surface of the second insulating pattern is a planar surface having a substantially flat profile.

14. The wiring substrate of claim 1, comprising a third wiring layer on the second wiring layer,
wherein the second wiring layer comprises a via pattern that (i) extends from a bottom surface of the second conductive pattern into the second insulating pattern and (ii) is coupled to a t op surface of the pad pattern.

15. A wiring substrate comprising:
a first wiring layer; and
a second wiring layer on the first wiring layer,
wherein the first wiring layer comprises
a first insulating pattern, and
a conductive pattern on the first insulating pattern,
wherein the second wiring layer comprises
a second insulating pattern on the first insulating pattern and covering the conductive pattern, and
an under-bump pattern on the second insulating pattern and coupled with an outer terminal,
wherein the conductive pattern comprises
a pad pattern and a wiring pattern extended from the pad pattern,
an intervening pattern (i) extending along a side surface of the pad pattern and side surfaces of the wiring pattern and (ii) spaced apart from the pad pattern and the wiring pattern by a first distance; and
a ground pattern (i) enclosing the pad pattern and the wiring pattern and (ii) spaced apart from the pad pattern and the wiring pattern by a second distance greater than the first distance,
wherein the under-bump pattern is on the pad pattern, and
wherein the under-bump pattern has a side surface crossing (i) the wiring pattern and (ii) the intervening pattern, in a plan view.

16. The wiring substrate of claim 15, wherein the second distance from the ground pattern to each of the pad pattern and the wiring pattern is uniform, and
wherein the intervening pattern comprises a plurality of linear patterns that are connected in series.

17. The wiring substrate of claim 16, wherein the intervening pattern has a partially open polygonal ring shape, in a plan view.

18. The wiring substrate of claim 15, wherein a top surface of the second insulating pattern comprises:
a first surface on the pad pattern;
a second surface on the ground pattern; and
a third surface between the pad pattern and the ground pattern and connecting the first surface to the second surface,
wherein each of the first surface and the second surface is a planar surface having a substantially flat profile,
wherein the third surface is a concave surface, the third surface being downwardly recessed from the first surface and the second surface, and
wherein a bottommost end of the third surface is at a level higher than a top surface of the conductive pattern.

19. The wiring substrate of claim 15, wherein the second wiring layer comprises a via pattern that extends from a bottom surface of the under-bump pattern into the second insulating pattern and that is coupled to a top surface of the pad pattern.

20. A semiconductor package, comprising:
a wiring substrate;
a semiconductor chip mounted on the wiring substrate; and
a connection terminal between the wiring substrate and the semiconductor chip and connecting the semiconductor chip to the wiring substrate,
wherein the wiring substrate comprises
a first insulating pattern,
a conductive pattern on the first insulating pattern,
a second insulating pattern on the first insulating pattern and covering the conductive pattern, and
an under-bump pattern on the second insulating pattern and coupled to the connection terminal,
wherein the conductive pattern comprises
a pad pattern and a wiring pattern extending from the pad pattern,
a ground pattern enclosing the pad pattern, in a plan view, and
an intervening pattern between the ground pattern and the pad pattern, and between the ground pattern and the wiring pattern,
wherein the under-bump pattern is on a connecting portion between the pad pattern and the wiring pattern, and
wherein the intervening pattern comprises a plurality of linear patterns connected in series.
